(19) United States
(12) Patent Application Publication
(10) Pub. No.: US 2020/0020711 A1
(43) Pub. Date: Jan. 16, 2020

(54) MEMORY DEVICE AND METHOD OF FABRICATING THE SAME

(71) Applicant: MACRONIX International Co., Ltd., Hsinchu (TW)

(72) Inventor: Ting-Feng Liao, New Taipei City (TW)

(73) Assignee: MACRONIX International Co., Ltd., Hsinchu (TW)

(21) Appl. No.: 16/035,421

(22) Filed: Jul. 13, 2018

(51) Int. Cl. H01L 27/11582; H01L 29/10; H01L 27/11565; H01L 21/311; H01L 21/28; H01L 21/02; H01L 21/768

(52) U.S. Cl. CPC H01L 27/11582; H01L 21/3212; H01L 27/11565; H01L 21/31116; H01L 21/28282; H01L 21/0262; H01L 21/02532; H01L 21/02595; H01L 21/02636; H01L 21/76877; H01L 21/7684; H01L 21/76802; H01L 21/02271; H01L 21/0228; H01L 21/02164; H01L 29/1037

(57) ABSTRACT

A memory device and a method of fabricating the same are provided. The memory device includes a substrate, a first circuit structure, a plurality of first conductive pillars, a second circuit structure, and a plurality of second conductive pillars. The first circuit structure is disposed on the substrate. The first conductive pillars are disposed in the first circuit structure and arranged along a first direction. The first conductive pillars are extended from an upper layer of the first circuit structure to the substrate. The second circuit structure is disposed on the first circuit structure. The second conductive pillars are disposed in the second circuit structure and arranged along the first direction. The second conductive pillars are extended from an upper layer of the second circuit structure to the first circuit structure. Each of the second conductive pillars is electrically connected to each of the first conductive pillars respectively.

### BACKGROUND OF THE INVENTION

### Field of the Invention

The invention relates to a semiconductor device and a method of fabricating the same, and particularly relates to a memory device and a method of fabricating the same.

### Description of Related Art

With the continuous development of science and technology, the demands for greater storage capacity also increase as electronic devices continue to improve. To satisfy the demands for high storage density, memory devices become smaller in size and have higher integrity. Therefore, the form of memory devices has developed from 2D memory devices having a planar gate structure to 3D memory devices having a vertical channel (VC) structure.

However, as integrity of 3D memory devices increases, it is necessary to form a trench with a high aspect ratio and fill a conductive material into the trench in a laminated structure of the memory devices in a manufacturing process of the memory devices. This will cause stress on the laminated structure, and thereby causing deformation of the trench and devices near the trench. The deformation may cause an alignment problem between an upper layer structure and a lower layer structure, or misconnection between the laminated structure and back-end-of-line (BEOL) routings and/or misalignment of the BEOL routings. Thus, how to improve the deformation of the structure of the memory device caused by the trench with a high aspect ratio is a problem to be solved at present.

### SUMMARY OF THE INVENTION

The invention provides a memory device and a method of fabricating the same that are capable of improving the problem of the deformation of the structure of the memory device caused by the trench with a high aspect ratio.

The invention provides a memory device including a substrate, a first circuit structure, a plurality of first conductive pillars, a second circuit structure, and a plurality of second conductive pillars. The first circuit structure is disposed on the substrate. The plurality of first conductive pillars are disposed in the first circuit structure and arranged along a first direction. The plurality of first conductive pillars are extended from an upper layer of the first circuit structure to the substrate. The second circuit structure is disposed on the first circuit structure. The plurality of second conductive pillars are disposed in the second circuit structure and arranged along the first direction. The plurality of second conductive pillars are extended from an upper layer of the second circuit structure to the first circuit structure. Each of the plurality of second conductive pillars is electrically connected to each of the plurality of first conductive pillars respectively.

According to some embodiments of the invention, the cross-sectional shapes of the plurality of first conductive pillars and the plurality of second conductive pillars include circles, ovals, squares, polygons, or combinations thereof.

According to some embodiments of the invention, a cross-section of the plurality of first conductive pillars has a first width in a second direction, the first direction and the second direction are perpendicular to each other, and a ratio of a height to the first width of the plurality of first conductive pillars is between 15 and 28.

According to some embodiments of the invention, a cross-section of the plurality of second conductive pillars has a second width in a second direction, the first direction and the second direction are perpendicular to each other, and a ratio of a height to the second width of the plurality of second conductive pillars is between 15 and 28.

According to some embodiments of the invention, an interval between two adjacent of the first conductive pillars and between two adjacent of the second conductive pillars is larger than or equal to 750 nm in the first direction respectively.

According to some embodiments of the invention, the first circuit structure and the second circuit structure include a plurality of first memory pillars and a plurality of second memory pillars respectively, and each of the plurality of first memory pillars is electrically connected to each of the plurality of second memory pillars respectively.

The invention provides a method of fabricating a memory device including the following steps. A first circuit structure is formed on a substrate. A plurality of first conductive pillars are formed in the first circuit structure. The plurality of first conductive pillars are arranged along a first direction and extended from an upper layer of the first circuit structure to the substrate. A second circuit structure is formed on the first circuit structure. A plurality of second conductive pillars are formed in the second circuit structure. The plurality of second conductive pillars are arranged along the first direction and extended from an upper layer of the second circuit structure to the first circuit structure. Each of the plurality of second conductive pillars is electrically connected to each of the plurality of first conductive pillars respectively.

According to some embodiments of the invention, the method of fabricating the memory device further includes the following steps. A plurality of first trenches are formed in the first circuit structure. The plurality of first trenches are arranged along a second direction and expose a portion of the substrate. The first direction and the second direction are perpendicular to each other. A first dielectric layer is formed to fill the plurality of first trenches. The plurality of first conductive pillars are formed in the plurality of first trenches filled with the first dielectric layer.

According to some embodiments of the invention, the method of fabricating the memory device further includes the following steps. A plurality of second trenches are formed in the second circuit structure. The plurality of second trenches are arranged along the second direction and expose a portion of the first circuit structure. A second dielectric layer is formed to fill the plurality of second trenches. The plurality of second conductive pillars are formed in the plurality of second trenches filled with the second dielectric layer.

According to some embodiments of the invention, the first circuit structure and the second circuit structure comprise a plurality of first memory pillars and a plurality of second memory pillars respectively, and each of the plurality of first memory pillars is electrically connected to each of the plurality of second memory pillars respectively.

Based on the above, in the memory device of the invention, the plurality of conductive pillars are substituted for the traditional long-narrow conductor trench structures. In comparison with the long-narrow conductor trench structures, the stress that the conductive pillars suffered is more uniform. Thus, the stack structure of the circuit structure in the memory device is less likely to tilt. That is, the circuit structure is less likely to deformation. In other words, in the memory device of the invention, the alignment between the circuit structures can be improved. Moreover, the misconnection between the circuit structure and the BEOL routings and/or the misalignment of the BEOL routings can also be improved.

In order to make the aforementioned features and advantages of the disclosure more comprehensible, embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A to FIG. 1J are cross-sectional schematic diagrams illustrating a manufacturing process of a memory device according to some embodiments of the invention.

FIG. 2 and FIG. 3 are respectively top views of FIG. 1A and FIG. 1B.

FIG. 4 is a top view of FIG. 1F and FIG. 1G.

### DESCRIPTION OF THE EMBODIMENTS

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

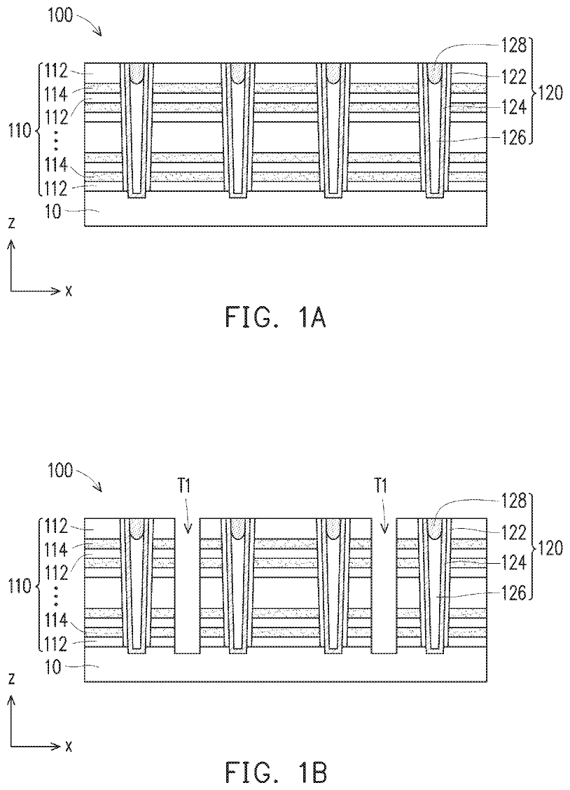

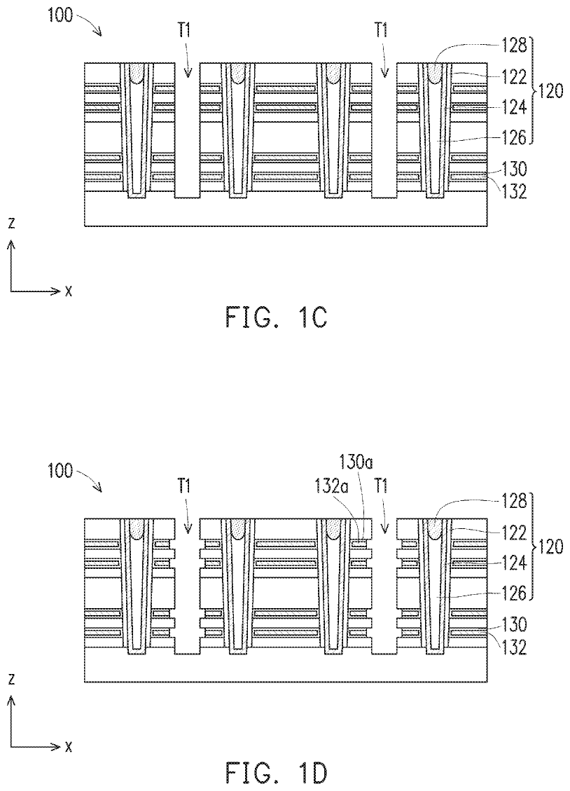

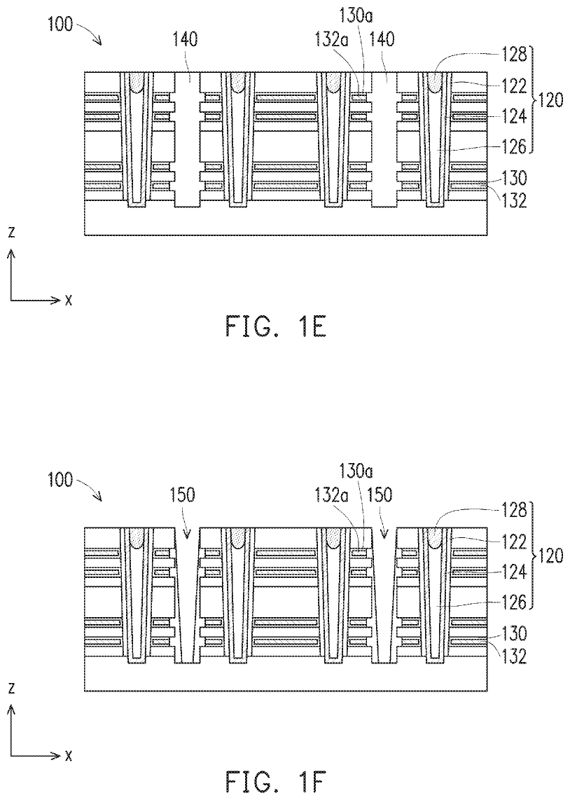

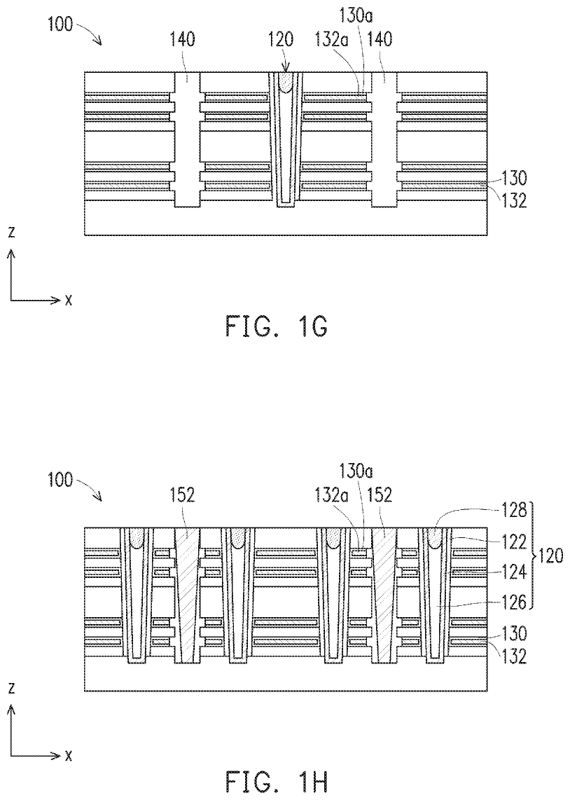

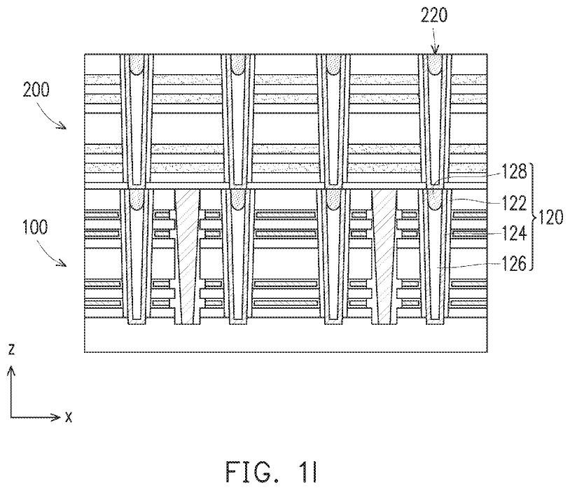

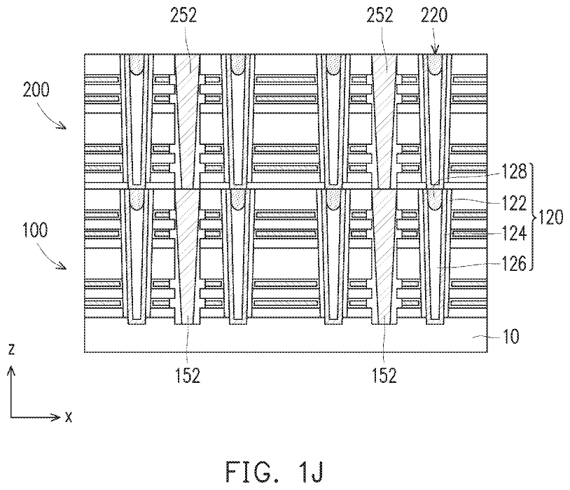

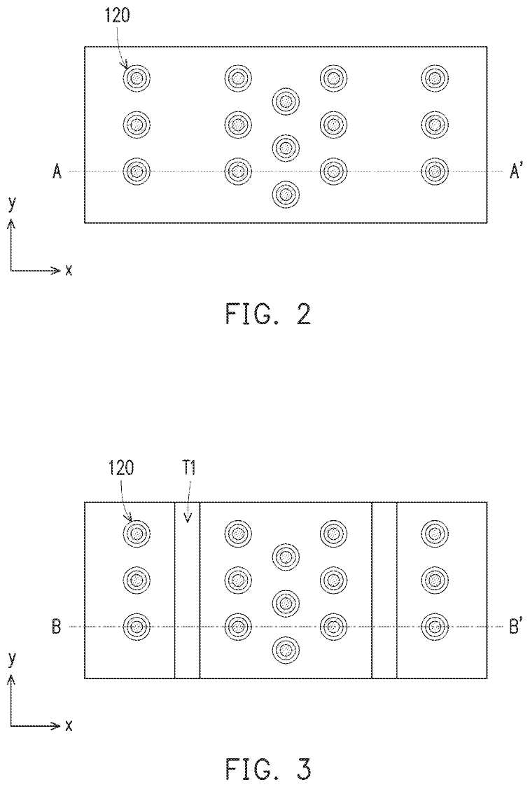

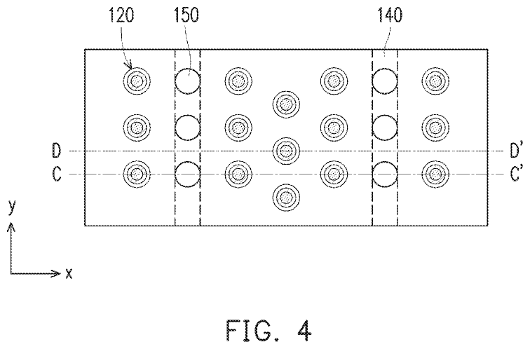

FIG. 1A to FIG. 1J are cross-sectional schematic diagrams illustrating a manufacturing process of a memory device according to some embodiments of the invention. FIG. 2 and FIG. 3 are respectively top views of FIG. 1A and FIG. 1B. FIG. 4 is a top view of FIG. 1F and FIG. 1G.

FIG. 1A is a cross-sectional view taken along a line A-A′ in FIG. 2. Referring to FIG. 1A and FIG. 2, a first circuit structure 100 is formed on a substrate 10. The substrate 10 includes a semiconductor substrate, such as a silicon substrate. In some embodiments, a doped region (e.g., an N+ doped region, not shown) may be formed in the substrate 10 based on design requirements. The first circuit structure 100 includes a stack structure 110 and a plurality of first memory pillars 120.

In some embodiments, the stack structure 110 includes a plurality of insulating layers 112 and a plurality of sacrificial layers 114 alternately stacked. A material of the insulating layer 112 includes a dielectric material, such as silicon oxide. A material of the sacrificial layer 114 is different from a material of the insulating layer 112, and the material of the sacrificial layer 114 exhibits a sufficient etching selectivity with respect to the insulating layer 112. In some embodiments, the material of the sacrificial layer 114 is silicon nitride, for example. The insulating layers 112 and the sacrificial layers 114 are formed by performing a plurality of chemical vapor deposition (CVD) processes, for example. A number of the insulating layers 112 and a number of the sacrificial layers 114 in the stack structure 110 may be 8 layers, 16 layers, 32 layers, 48 layers, 96 layers, or more layers, but the invention is not limited thereto. The number of the insulating layers 112 and the number of the sacrificial layers 114 in the stack structure 110 may be determined by the design and the density of the memory device.

In some embodiments, a method of forming the plurality of first memory pillars 120 is described as below. Specifically, first, a plurality of openings (not shown) are formed in the stack structure 110. The openings penetrate through the stack structure 110 to expose a portion of the substrate 10. In some embodiments, a method of forming the openings includes performing a patterning process on the stack structure 110. In a particular embodiment, the patterning process includes a hole etch, for example, so as to form a plurality of cylindrical openings penetrating through the stack structure 110, but the invention is not limited thereto. Then, a charge storage structure 122 is formed in the openings. Specifically, a charge storage material (not shown) is formed on the substrate 10. The charge storage material conformally covers a bottom surface and sidewalls of the openings and a top surface of the stack structure 110. Thereafter, an etching process is performed to remove the charge storage material on the bottom surface of the openings and the top surface of the stack structure 110, such that the charge storage structure 122 is conformally formed on the sidewalls of the openings. In some embodiments, the charge storage structure 122 may be a composite structure including oxide layer/nitride layer/oxide layer (ONO), for example. In some embodiments, a method of forming the charge storage material includes a CVD process or an atomic layer deposition (ALD) process, for example. In some embodiments, the etching process includes, for example, an anisotropic etching process, such as a reactive-ion etching (RIE) process. Then, a thin film 124 is formed on the substrate 10. The thin film 124 conformally covers the bottom surface of the openings and surfaces of the charge storage structure 122. In some embodiments, a material of the thin film 124 includes a semiconductor material, such as polycrystalline silicon. A method of forming the thin film 124 includes a CVD process, for example. In some embodiments, the thin film 124 may act as a vertical channel structure subsequently. Thereafter, an insulating structure 126 is formed in the openings. The insulating structure 126 is filled in the openings, and a top surface of the insulating structure 126 is lower than the top surface of the stack structure 110. In other words, the insulating structure 126 does not fully fill the openings. In some embodiments, a material of the insulating structure 126 includes spin-on dielectrics (SOD), for example. The spin-on dielectrics may be silicon oxide or other insulating materials, for example. Lastly, a plug 128 is formed in the openings. Specifically, a conductive material is deposited to fill an upper portion of the openings, followed by chemical mechanical polishing (CMP) processes and/or etch back processes to remove the conductive material on the top surface of the stack structure 110. In some embodiments, a material of the plug 128 includes polycrystalline silicon or doped polycrystalline silicon, for example. At this point, the manufacturing process of the plurality of first memory pillars 120 is completed. In some embodiments, the first memory pillars 120 may be arranged in an array, in a staggered line pattern, or in a random, for example. In the embodiment, as shown in FIG. 2, the first memory pillars 120 located in a middle region are arranged in a staggered line pattern, for example, but the invention is not limited thereto.

FIG. 1B is a cross-sectional view taken along a line B-B′ in FIG. 3. Referring to FIG. 1B and FIG. 3, a plurality of trenches T1 are formed in the first circuit structure 100 and arranged along an X-direction. Particularly, a patterning process is performed on the stack structure 110 to form the trenches T1 penetrating through the insulating layers 112 and the sacrificial layers 114. The trenches T1 penetrate through the stack structure 110 to expose a portion of the substrate 10.

Referring to FIG. 1C, a gate replacement process is performed. The sacrificial layers 114 in the stack structure 110 are replaced with conductive materials as a gate. Specifically, first, the sacrificial layers 114 exposed by the trenches T1 are removed to form a lateral openings (not shown) exposing a portion of the charge storage structure 122 and surfaces of the insulating layers 112. A method of removing the sacrificial layers 114 exposed by the trenches T1 may be a wet etching method, for example. An etchant used in the wet etching method may be a H₃PO₄ solution, for example. Then, a buffer material layer 130 is formed on the exposed surfaces of the charge storage structure 122 and the insulating layers 112. A material of the buffer material layer 130 may be, for example, a high-k material having a dielectric constant greater than 7, such as Al₂O₃. A method of forming the buffer material layer 130 includes a CVD process or an ALD process, for example. Then, a gate conductive material layer 132 is formed to fill the lateral openings. A material of the gate conductive material layer 132 includes tungsten (W), tungsten nitride (WN), tantalum (Ta), tantalum nitride (TaN), titanium (Ti), titanium nitride (TiN), or a combination thereof, for example. A method of forming the gate conductive material layer 132 includes a CVD process or a physical vapor deposition (PVD) process, for example.

Referring to FIG. 1D, a portion of the gate conductive material layer 132 and a portion of the buffer material layer 130 are removed to form recesses on the sidewalls of the trenches T1. In other words, sidewalls of a gate conductive material layer 132a and a buffer material layer 130a are indented from the sidewalls of the insulating layers 112. In some embodiments, a method of removing the portion of the gate conductive material layer 132 and the portion of the buffer material layer 130 may be an etch back method, such as a wet etching method.

Referring to FIG. 1E, a dielectric layer 140 is formed to fill the trenches T1. In some embodiments, a material of the dielectric layer 140 is silicon nitride, for example. A method of forming the dielectric layer 140 includes a CVD process or an ALD process, for example.

FIG. 1F is a cross-sectional view taken along a line C-C′ in FIG. 4. FIG. 1G is a cross-sectional view taken along a line D-D′ in FIG. 4. Referring to FIG. 1F, FIG. 1G, and FIG. 4, a plurality of openings 150 are formed in the first circuit structure 100 and arranged along a Y-direction. Particularly, the plurality of openings 150 are formed in the trenches T1 filled with the dielectric layer 140. The openings 150 penetrate through the dielectric layer 140 to expose a portion of the substrate 10. In some embodiments, a method of forming the openings 150 includes performing a patterning process on the dielectric layer 140. In a particular embodiment, the patterning process includes, for example, a hole etch, so as to form a plurality of cylindrical openings 150 penetrating through the dielectric layer 140, but the invention is not limited thereto. The cross-sectional shapes of the openings 150 may include circles, ovals, squares, polygons, or combinations thereof. Therefore, the cross-sectional shapes of first conductive pillars 152 formed by the subsequent steps may include circles, ovals, squares, polygons, or combinations thereof. In some embodiments, the cross-sectional shapes of the openings 150 (or the first conductive pillars 152) may be determined by the design or the process conditions of the memory device. In some embodiments, the position of the openings 150 may be aligned with the first memory pillars 120 in the X-direction (as shown in FIG. 1F). In some other embodiments, the position of the openings 150 may not be aligned with the first memory pillars 120 in the X-direction (as shown in FIG. 1G), but the invention is not limited thereto. In some embodiments, the plurality of openings 150 (or the first conductive pillars 152) are discontinuously arranged along the Y-direction. Namely, there is an interval between two adjacent openings 150. In other words, the positions and the numbers of the openings 150 (or the first conductive pillars 152) may be determined by the design of the memory device. For instance, the density of the openings 150 (or the first conductive pillars 152) may be increased to reduce the resistance. Namely, the interval between the two adjacent openings 150 is reduced.

It should be noted that, in some embodiments, the width of the openings 150 in the X-direction may be less than or equal to the width of the trenches T1 in the X-direction. In some other embodiments, the width of the openings 150 in the X-direction may be larger than the width of the trenches T1 in the X-direction, as long as the first conductive pillars 152 formed by the subsequent steps will not be in direct contact with the gate conductive material layer 132a. In other words, there is the dielectric layer isolating the first conductive pillars 152 formed by the subsequent steps from the gate conductive material layer 132a.

Referring to FIG. 1H, a conductive material layer is formed to fill the openings 150. In some embodiments, a material of the conductive material layer is polycrystalline silicon, amorphous silicon, Ti, TiN, W, WN, Ta, TaN, aluminum (Al), copper (Cu), cobalt (Co), or a combination thereof, for example. A method of forming the conductive material layer includes a CVD process or an ALD process, for example. Then, CMP processes and/or etch back processes may be performed to remove the conductive material layer on the top surface of the stack structure 110. At this point, the plurality of first conductive pillars 152 are formed in the first circuit structure 100 and arranged along the Y-direction, wherein the plurality of first conductive pillars 152 are extended from the upper layer of the first circuit structure 100 to the substrate 10. In some embodiments, since the plurality of openings 150 are formed in the trenches T1 filled with the dielectric layer 140, the formed plurality of first conductive pillars 152 are also formed in the trenches T1 filled with the dielectric layer 140.

It should be noted that, in the embodiment, the plurality of conductive pillars are substituted for the traditional long-narrow conductor trench structures. In comparison with the long-narrow conductor trench structures, the stress that the conductive pillars suffered from the surroundings is more uniform. Particularly, when the cross section of the conductive pillars is circular, the suffered stress is most uniform. Thus, the stack structure of the circuit structure is less likely to tilt. In other words, in the embodiment, by forming the plurality of conductive pillars to be substituted for the traditional long-narrow conductor trench structures, the circuit structure is less likely to deformation. Therefore, in the subsequent processes, the alignment problem between the upper layer structures and the circuit structure can be improved. Moreover, the misconnection between the circuit structure and the BEOL routings and/or the misalignment of the BEOL routings can be also improved.

Referring to FIG. 1I, in the embodiment, a second circuit structure 200 is formed according to the aforementioned method of forming the first circuit structure 100. The structures, materials, numbers of layers, and forming methods of the second circuit structure 200 and the first circuit structure 100 may be the same or different, which may be adjusted according to the design requirements. In the embodiment, the structure of the second circuit structure 200 is the same as the structure of the first circuit structure 100, but the invention is not limited thereto. Particularly, the second circuit structure 200 includes a plurality of second memory pillars 220. The second circuit structure 200 is stacked on the first circuit structure 100, wherein the second memory pillars 220 are respectively extended from an upper layer of the second circuit structure 200 to the first circuit structure 100, and each of the second memory pillars 220 is electrically connected to each of the first memory pillars 120 respectively. In some embodiments, a method of stacking the second circuit structure 200 on the first circuit structure 100 is not particularly limited. For instance, the second circuit structure 200 may be directly stacked on the first circuit structure 100. The substrate of the second circuit structure 200 may be completely removed or partially removed, as long as each of the second memory pillars 220 may be electrically connected to each of the first memory pillars 120 respectively. In the embodiment, the substrate of the second circuit structure 200 is partially removed (as shown in FIG. 1I), for example, but the invention is not limited thereto.

Referring to FIG. 1J, then, in the embodiment, a plurality of second conductive pillars 252 are formed in the second circuit structure 200 according to the aforementioned method of forming the first conductive pillars 152. The structures, materials, and forming methods of the second conductive pillars 252 and the first conductive pillars 152 may be the same or different, which may be adjusted according to the design requirements. Particularly, a plurality of trenches (not shown) are formed in the second circuit structure 200 and arranged along the X-direction, wherein the trenches expose a portion of the first circuit structure 100. Then, a dielectric layer (not shown) is formed to fill the trenches. Thereafter, a plurality of openings (not shown) are formed in the second circuit structure 200 and arranged along the Y-direction. Subsequently, a conductive material is filled in the plurality of openings to form the plurality of second conductive pillars 252. The plurality of second conductive pillars 252 are formed in the second circuit structure 200 and arranged along the Y-direction, wherein the plurality of second conductive pillars 252 are extended from the upper layer of the second circuit structure 200 to the first circuit structure 100, and each of the second conductive pillars 252 is electrically connected to each of the first conductive pillars 152 respectively. In some embodiments, the plurality of second conductive pillars 252 are formed in the plurality of trenches filled with the dielectric layer.

In some embodiments, the gate conductive material layer may be used as word lines, the thin film may be used as bit lines, and the conductive pillars may be used as common source lines. However, the invention is not limited thereto.

It should be noted that, in the embodiment, as described above, the plurality of conductive pillars are substituted for the traditional long-narrow conductor trench structures. Since the stress that the conductive pillars suffered from the surroundings is more uniform, the stack structure of the circuit structure is less likely to tilt. In other words, in the embodiment, since the first circuit structure 100 is less likely to deformation, the misalignment is less likely to happen when the second circuit structure 200 is stacked on the first circuit structure 100. In the embodiment, it is illustrated by stacking two circuit structures with the same structure, but the invention is not limited thereto. In other embodiments, it is possible to stack two circuit structures with different structures. Additionally, in other embodiments, it is also possible to stack more than two circuit structures, and is not limited to stack only two circuit structures. Therefore, in the embodiments of the invention, the alignment between the circuit structures can be improved. Moreover, the misconnection between the circuit structure and the BEOL routings and/or the misalignment of the BEOL routings can be also improved.

In the following, the structure of the memory device of the invention is described with reference to FIG. 1J. Besides, the method of fabricating the memory device according to the embodiment is described by taking the above processes as an example, but the method of fabricating the memory device of the invention is not limited thereto.

Referring to FIG. 1J, the memory device includes the substrate 10, the first circuit structure 100, the plurality of first conductive pillars 152, the second circuit structure 200, and the plurality of second conductive pillars 252. The first circuit structure 100 is disposed on the substrate 10. The plurality of first conductive pillars 152 are disposed in the first circuit structure 100 and arranged along the Y-direction, wherein the plurality of first conductive pillars 152 are extended from the upper layer of the first circuit structure 100 to the substrate 10. The second circuit structure 200 is disposed on the first circuit structure 100. The plurality of second conductive pillars 252 are disposed in the second circuit structure 200 and arranged along the Y-direction, wherein the plurality of second conductive pillars 252 are extended from the upper layer of the second circuit structure 200 to the first circuit structure 100, and each of the second conductive pillars 252 is electrically connected to each of the first conductive pillars 152 respectively.

In some embodiments, the cross-sectional shapes of the plurality of first conductive pillars 152 and the plurality of second conductive pillars 252 include circles, ovals, squares, polygons, or combinations thereof. In some embodiments, the cross section of the first conductive pillars 152 has a first width in the X-direction. A ratio of a height to the first width of the first conductive pillars 152 is between 15 and 28. In some embodiments, the cross section of the second conductive pillars 252 has a second width in the X-direction. A ratio of a height to the second width of the second conductive pillars 252 is between 15 and 28. In some embodiments, an interval between two adjacent of the first conductive pillars 152 and between two adjacent of the second conductive pillars 252 is larger than or equal to 750 nm in the Y-direction respectively, for example, but the invention is not limited thereto. In some embodiments, the first circuit structure 100 and the second circuit structure 200 include the plurality of first memory pillars 152 and the plurality of second memory pillars 252 respectively, and each of the first memory pillars 152 is electrically connected to each of the second memory pillars 252 respectively.

In summary, in the memory device of the invention, the plurality of conductive pillars are substituted for the traditional long-narrow conductor trench structures. In comparison with the long-narrow conductor trench structures, the stress that the conductive pillars suffered is more uniform. Thus, the stack structure of the circuit structure in the memory device is less likely to tilt. That is, the circuit structure is less likely to deformation. In other words, in the memory device of the invention, the alignment between the circuit structures can be improved. Moreover, the misconnection between the circuit structure and the BEOL routings and/or the misalignment of the BEOL routings can also be improved.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

1. A memory device, comprising:
a substrate;
a first circuit structure, disposed on the substrate;
a plurality of first conductive pillars, disposed in the first circuit structure and arranged along a first direction, wherein the plurality of first conductive pillars are extended from an upper layer of the first circuit structure to the substrate;
a second circuit structure, disposed on the first circuit structure; and
a plurality of second conductive pillars, disposed in the second circuit structure and arranged along the first direction, wherein the plurality of second conductive pillars are extended from an upper layer of the second circuit structure to the first circuit structure, and each of the plurality of second conductive pillars is electrically connected to each of the plurality of first conductive pillars respectively.

2. The memory device according to claim 1, wherein cross-sectional shapes of the plurality of first conductive pillars and the plurality of second conductive pillars comprise circles, ovals, squares, polygons, or combinations thereof.

3. The memory device according to claim 1, wherein a cross-section of the plurality of first conductive pillars has a first width in a second direction, the first direction and the second direction are perpendicular to each other, and a ratio of a height to the first width of the plurality of first conductive pillars is between 15 and 28.

4. The memory device according to claim 1, wherein a cross-section of the plurality of second conductive pillars has a second width in a second direction, the first direction and the second direction are perpendicular to each other, and a ratio of a height to the second width of the plurality of second conductive pillars is between 15 and 28.

5. The memory device according to claim 1, wherein an interval between two adjacent of the first conductive pillars and between two adjacent of the second conductive pillars is larger than or equal to 750 nm in the first direction respectively.

6. The memory device according to claim 1, wherein the first circuit structure and the second circuit structure comprise a plurality of first memory pillars and a plurality of second memory pillars respectively, and each of the plurality of first memory pillars is electrically connected to each of the plurality of second memory pillars respectively.

7. A method of fabricating a memory device, comprising:
forming a first circuit structure on a substrate;
forming a plurality of first conductive pillars in the first circuit structure, wherein the plurality of first conductive pillars are arranged along a first direction and extended from an upper layer of the first circuit structure to the substrate;
forming a second circuit structure on the first circuit structure; and
forming a plurality of second conductive pillars in the second circuit structure, wherein the plurality of second conductive pillars are arranged along the first direction and extended from an upper layer of the second circuit structure to the first circuit structure, and each of the plurality of second conductive pillars is electrically connected to each of the plurality of first conductive pillars respectively.

8. The method of fabricating the memory device according to claim 7, further comprising:
forming a plurality of first trenches in the first circuit structure, wherein the plurality of first trenches are arranged along a second direction and expose a portion of the substrate, and the first direction and the second direction are perpendicular to each other; and
forming a first dielectric layer filling the plurality of first trenches,
wherein the plurality of first conductive pillars are formed in the plurality of first trenches filled with the first dielectric layer.

9. The method of fabricating the memory device according to claim 8, further comprising:
forming a plurality of second trenches in the second circuit structure, wherein the plurality of second trenches are arranged along the second direction and expose a portion of the first circuit structure; and
forming a second dielectric layer filling the plurality of second trenches,
wherein the plurality of second conductive pillars are formed in the plurality of second trenches filled with the second dielectric layer.

10. The method of fabricating the memory device according to claim 7, wherein the first circuit structure and the second circuit structure comprise a plurality of first memory pillars and a plurality of second memory pillars respectively, and each of the plurality of first memory pillars is electrically connected to each of the plurality of second memory pillars respectively.
